(19) United States
(12) Patent Application Publication
(10) Pub. No.: US 2024/0405065 A1
(43) Pub. Date: Dec. 5, 2024

(54) SEMICONDUCTOR DEVICE AND MANUFACTURE METHOD OF THEREOF

(71) Applicant: HON HAI PRECISION INDUSTRY CO., LTD., New Taipei City (TW)

(72) Inventors: Chia-Lung HUNG, New Taipei City (TW); Yi-Kai HSIAO, New Taipei City (TW); Hao-Chung KUO, New Taipei City (TW)

(21) Appl. No.: 18/677,905

(22) Filed: May 30, 2024

(30) Foreign Application Priority Data
Jun. 2, 2023 (TW) 112120753

(51) Int. Cl. H01L 29/06; H01L 21/265; H01L 21/266; H01L 29/66; H01L 29/78

(52) U.S. Cl. CPC H01L 29/0626; H01L 21/26513; H01L 21/266; H01L 29/66734; H01L 29/7813

(57) ABSTRACT

A method of manufacturing a semiconductor device is provided, including: forming a first conductive type lightly doped region in the epitaxial layer; forming a first conductive type heavily doped region and a second conductive type heavily doped region in the epitaxial layer on the first conductive type lightly doped region, in which the neighboring first conductive type heavily doped regions are spaced apart by the second conductive type heavily doped region; disposing the mask on the second conductive type heavily doped region; disposing a spacer on a sidewall of the mask; doping a first conductive type dopant in the first conductive type lightly doped region to form an anti-breakdown region; removing the mask and forming a trench extending into the second conductive type heavily doped region, first conductive type lightly doped region and the epitaxial layer; and removing the spacer.

### CROSS-REFERENCE TO RELATED APPLICATION

This application claims priority to Taiwan Application Serial Number 112120753, filed Jun. 2, 2023, which is herein incorporated by reference.

### BACKGROUND

### Field of Invention

A semiconductor device and a manufacture method thereof are provided in some embodiments of the present disclosure.

### Description of Related Art

Trench Gate Metal-Oxide-Semiconductor Field-Effect Transistor reduces the volume occupied by gate electrodes and channels in the semiconductor device by burying the gate electrode and the channel in trenches. However, since the channels are buried, the concentration of the dopant in the doping area around the channels is hardly regulated. In addition, if the photomask is used to define each doping area, the problem of alignment deviation will arise.

Therefore, there is a need to provide a method of manufacturing doping areas having different doping concentrations by reducing photomask-defining steps.

### SUMMARY

Some embodiments of the present disclosure provides a method of manufacturing a semiconductor device, including: providing a substrate, in which the substrate includes a base material and an epitaxial layer on the base material; forming a first conductive type lightly doped region in the epitaxial layer; forming a plurality of first conductive type heavily doped regions and a second conductive type heavily doped region in the epitaxial layer on the first conductive type lightly doped region, in which the plurality of first conductive type heavily doped regions neighboring to each other are spaced apart by the second conductive type heavily doped region; disposing a mask on the second conductive type heavily doped region; disposing a spacer on a sidewall of the mask; doping a first conductive type dopant in the first conductive type lightly doped region, thereby forming an anti-breakdown region; removing the mask and forming a trench extending into the second conductive type heavily doped region, the first conductive type lightly doped region and the epitaxial layer; and removing the spacer.

In some embodiments, a material of the mask and a material of the spacer are different.

In some embodiments, in a cross-sectional view, a projection of the spacer projected along a vertical direction falls within the second conductive type heavily doped region.

In some embodiments, in the cross-sectional view, a width of the projection of the spacer projected along the vertical direction and falling within the second conductive type heavily doped region is from 0.1 μm to 1 μm.

In some embodiments, a concentration of the first conductive type dopant in the anti-breakdown region is higher than a concentration of the first conductive type dopant in each of the plurality of first conductive type heavily doped regions.

Some embodiments of the present disclosure provides a method of manufacturing a semiconductor device, including: providing a substrate, in which the substrate includes a base material and an epitaxial layer on the base material; forming a first conductive type lightly doped region in the epitaxial layer; forming a plurality of first conductive type heavily doped regions and a second conductive type heavily doped region in the epitaxial layer on the first conductive type lightly doped region, in which the plurality of first conductive type heavily doped regions neighboring to each other are spaced apart by the second conductive type heavily doped region; forming a trench extending into the second conductive type heavily doped region, the first conductive type lightly doped region and the epitaxial layer; disposing a mask filling the trench, in which a top surface of the mask is higher than a top surface of the second conductive type heavily doped region; disposing a spacer on a sidewall of the mask; doping a first conductive type dopant in the first conductive type lightly doped region, thereby forming an anti-breakdown region; and removing the mask and the spacer to expose the trench.

In some embodiments, the step of disposing the mask filling the trench includes making the mask fill up the trench and protrude from the trench.

Some embodiments of the present disclosure provides a semiconductor device, including a substrate, a first conductive type lightly doped region, an anti-breakdown region, a plurality of second conductive type heavily doped region and a plurality of first conductive type heavily doped regions. The substrate includes a base material and an epitaxial layer on the base material. The first conductive type lightly doped region is disposed on the epitaxial layer. The anti-breakdown region is disposed in the first conductive type lightly doped region, in which a bottom surface of the anti-breakdown region and a lateral surface of the anti-breakdown region neighboring to the bottom surface directly contact the first conductive type lightly doped region, in which a concentration of a first conductive type dopant in the anti-breakdown region is higher than a concentration of the first conductive type dopant in the first conductive type lightly doped region. The plurality of second conductive type heavily doped regions are neighboring to the first conductive type lightly doped region and the anti-breakdown region, in which the plurality of second conductive type heavily doped regions neighboring to each other are spaced apart by a trench, and the trench extends from a position between the plurality of second conductive type heavily doped regions to the first conductive type lightly doped region and the epitaxial layer, making the first conductive type lightly doped region be located between the anti-breakdown region and the trench. Each of the plurality of first conductive type heavily doped regions is neighboring to each of the plurality of second conductive type heavily doped regions.

In some embodiments, in a cross-sectional view, a space between the anti-breakdown region and the trench is from 0.1 μm to 1 μm.

In some embodiments, the semiconductor device further includes a gate dielectric layer disposed on the trench and a gate layer disposed on the gate dielectric layer.

In some embodiments, the anti-breakdown region directly contacts each of the plurality of second conductive type heavily doped regions.

In some embodiments, the first conductive type lightly doped region encapsulates the anti-breakdown region to make the anti-breakdown region and each of the plurality of second conductive type heavily doped regions be spaced apart by the first conductive type lightly doped region.

In some embodiments, in a cross-sectional view, a projection of each of the plurality of second conductive type heavily doped regions and each of the plurality of first conductive type heavily doped regions projected along a vertical direction covers a projection of the anti-breakdown region projected along the vertical direction.

In some embodiments, in a cross-sectional view, a projection of each of the plurality of second conductive type heavily doped regions projected along a vertical direction covers a projection of the anti-breakdown region projected along the vertical direction.

In some embodiments, the anti-breakdown region includes a first anti-breakdown region and a second anti-breakdown region, and the first anti-breakdown region and the second anti-breakdown region are located on opposite sides of the trench, respectively.

It is to be understood that both the foregoing general description and the following detailed description are examples and are intended to provide further explanation of the present disclosure as claimed.

### BRIEF DESCRIPTION OF THE DRAWINGS

In order to allow the present disclosure to be more clearly understood, accompanying drawing is described as follows:

FIG. 1 exemplarily illustrates a method of manufacturing a semiconductor device according to some embodiments of the present disclosure.

FIG. 2A to FIG. 2K exemplarily illustrate cross-sectional schematic diagrams of each intermediate stage in a method of manufacturing a semiconductor device according to some embodiments of the present disclosure.

FIG. 3A to FIG. 3E exemplarily illustrate cross-sectional schematic diagrams of each intermediate stage in a method of manufacturing a semiconductor device according to some other embodiments of the present disclosure.

FIG. 4A to FIG. 4D exemplarily illustrate cross-sectional schematic diagrams of each intermediate stage in a method of manufacturing a semiconductor device according to some other embodiments of the present disclosure.

### DETAILED DESCRIPTION

It is to be understood that different implementations or embodiments provided in the following may implement different features of the subject matter of the present disclosure. The embodiments of specific components and arrangements are used to simplify the disclosure and not to limit the disclosure. Of course, these are only examples and are not intended to be limiting. For example, the description below that the first feature is formed on the second feature includes the two being in direct contact, or there are other additional features between the two that are not in direct contact. Furthermore, the present disclosure may repeat reference numerals and/or symbols in the various embodiments. Such repetition is for simplicity and clarity and does not represent a relationship between the various embodiments and/or configurations discussed.

Terms used in this specification generally have their ordinary meanings in the art and in the context in which they are used. The embodiments used in this specification, including examples of any terms discussed herein, are illustrative only and do not limit the scope and meaning of the disclosure or any exemplified terms. Likewise, the present disclosure is not limited to some of the implementations provided in this specification.

It will be understood that, although the terms “first,” “second,” etc., may be used herein to describe various elements, these elements should not be limited by these terms. These terms are used to distinguish one element from another. For example, a first element could be termed a second element, and similarly, a second element could be termed a first element, without departing from the scope of the embodiments.

As used herein, the phrase “and/or” includes any and all combinations of one or more of the associated listed items.

As used herein, the terms “comprise,” “include,” “has,” etc. are to be understood as open-ended, that is, to mean including but not limited to.

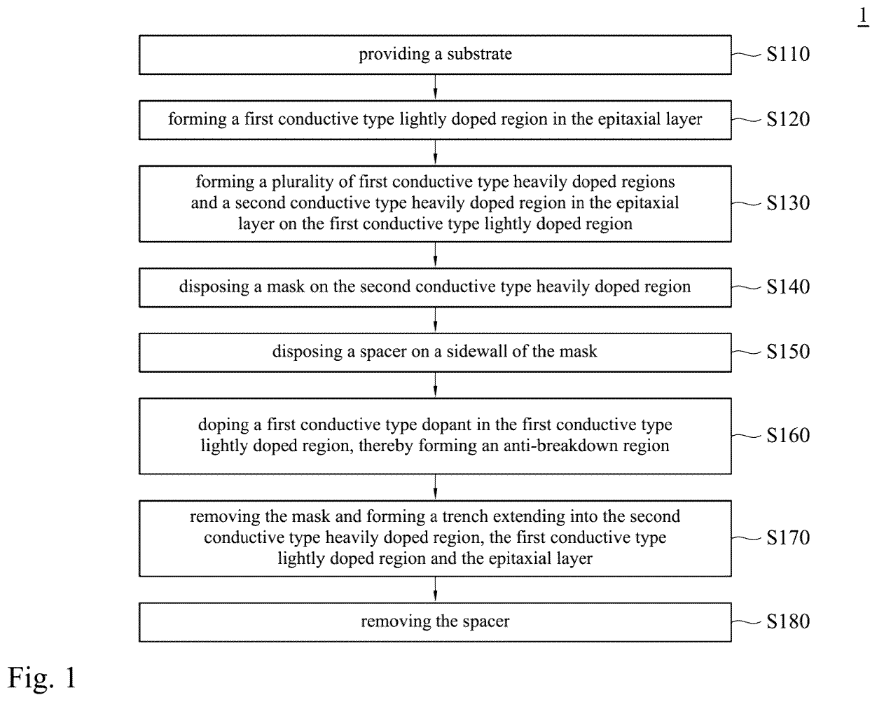

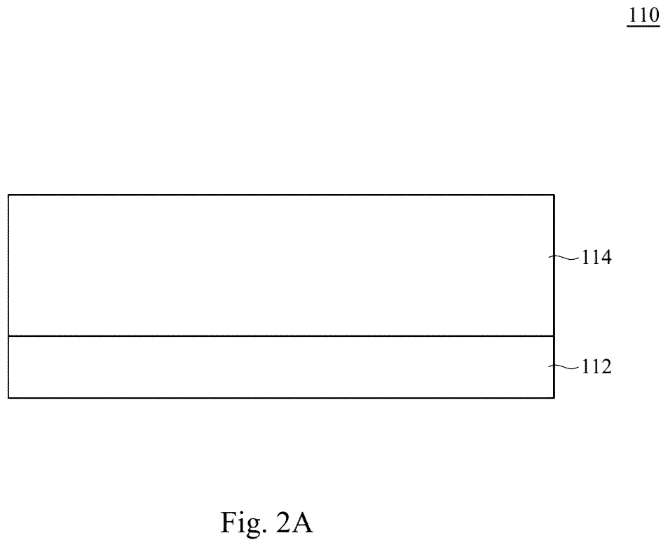

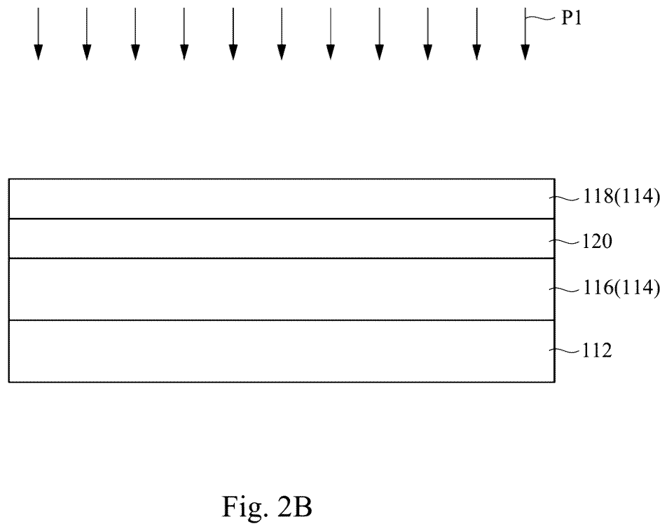

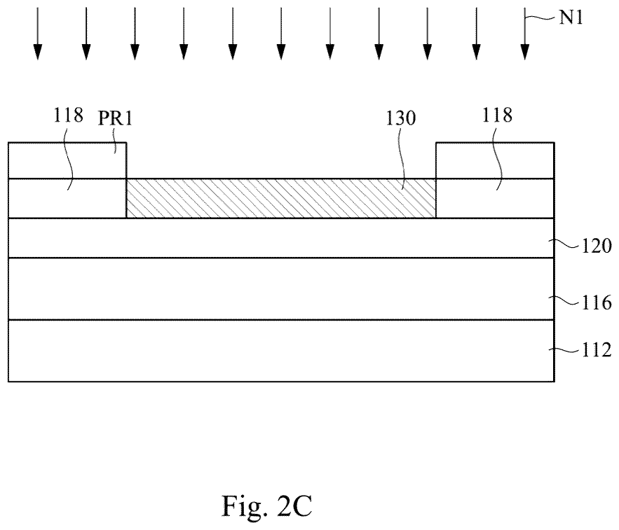

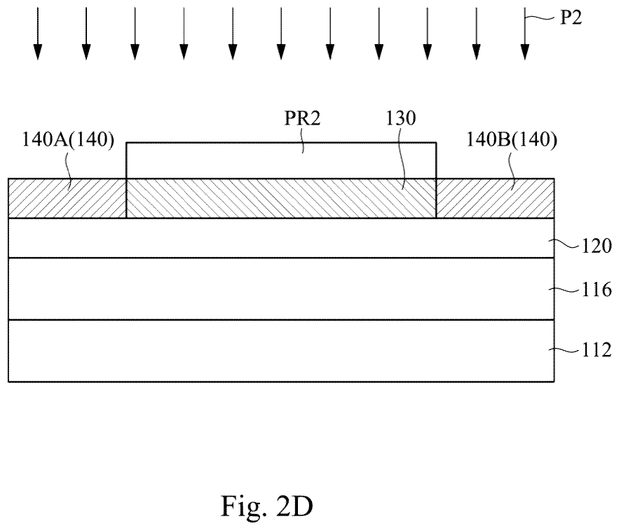

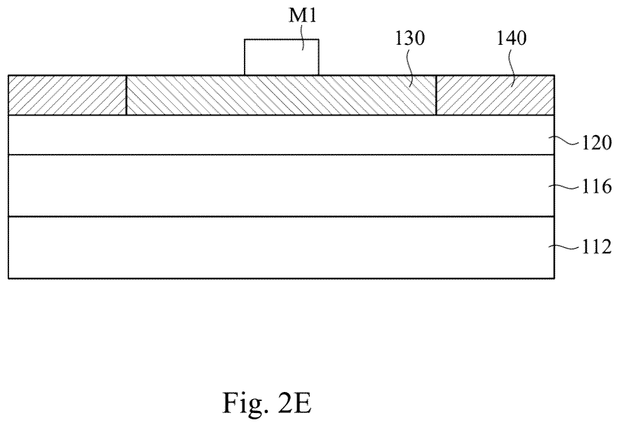

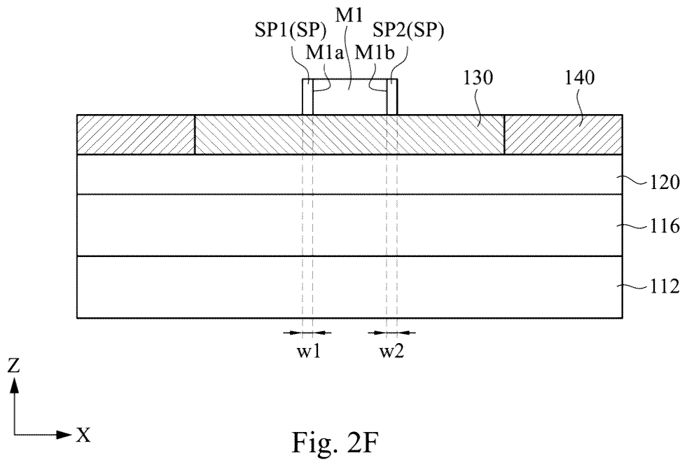

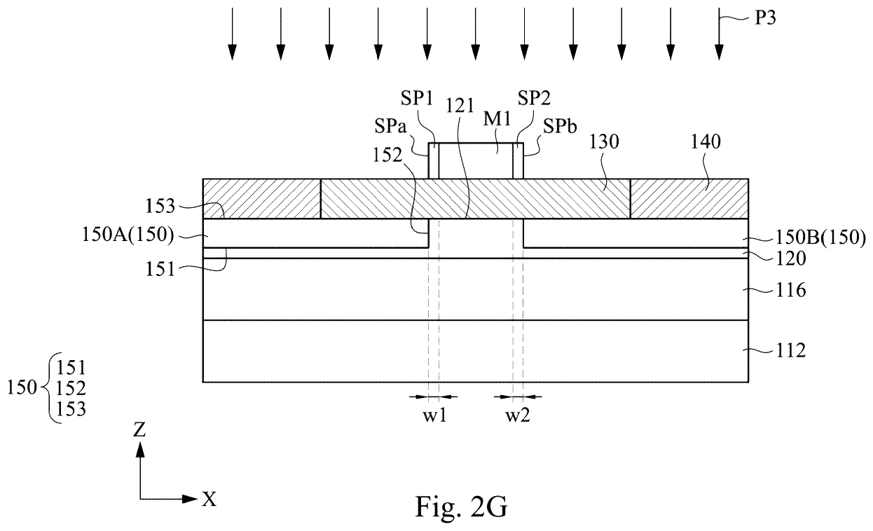

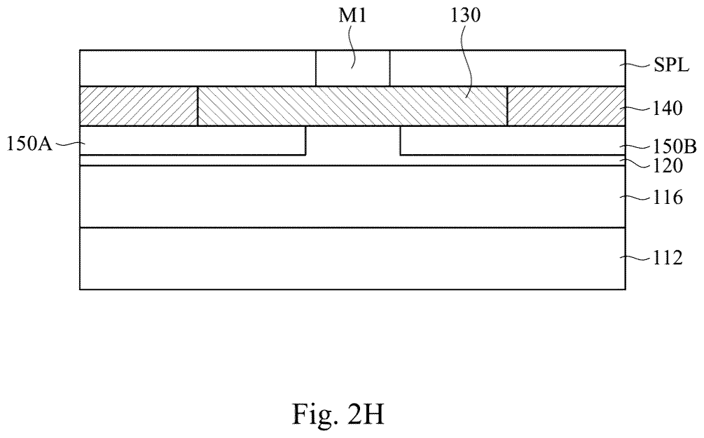

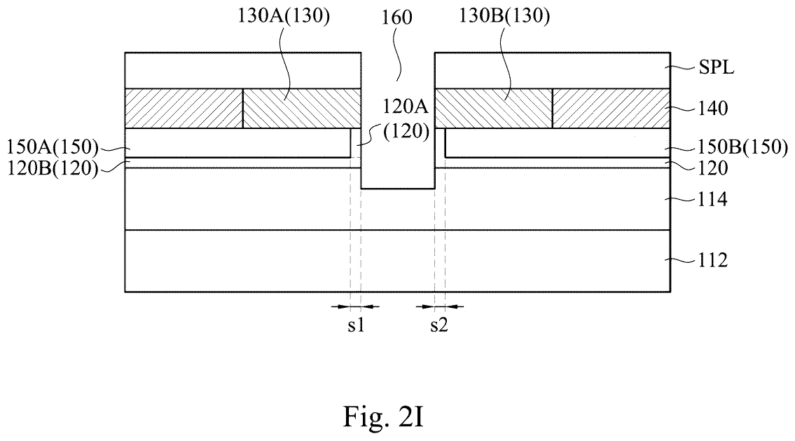

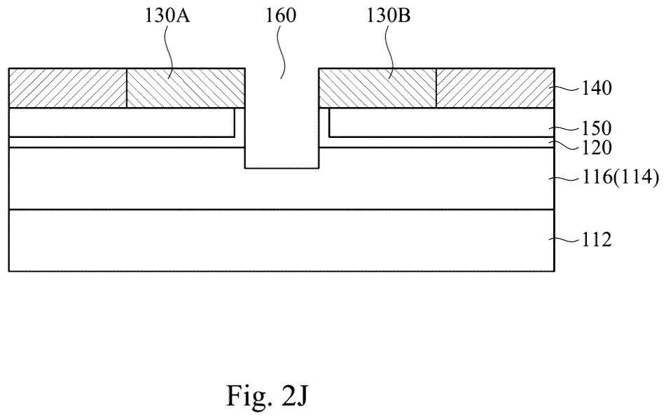

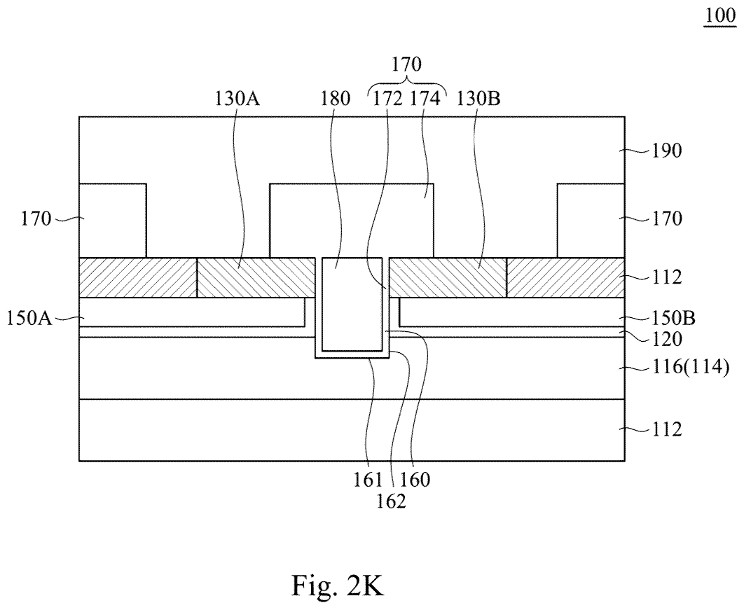

FIG. 1 exemplarily illustrates a method 1 of manufacturing a semiconductor device in some embodiments of the present disclosure. In order to facilitate the explanation of steps S110 to S180 in FIG. 1, please refer to FIG. 2A to FIG. 2K at the same time, exemplarily illustrating cross-sectional schematic diagrams of each intermediate stage in the method 1 of manufacturing a semiconductor device in some embodiments of the present disclosure.

First, please refer to step S110 of FIG. 1 and FIG. 2A, a substrate 110 is provided.

In some embodiments, the substrate 110 includes a base material 112 and an epitaxial layer 114 on the base material 112. In some embodiments, a material of the base material 112 can be a semiconductor base material, such as silicon, silicon germanium, silicon carbide or combinations thereof. In some embodiments, the epitaxial layer 114 can be doped by dopants with specific semiconductor type. For example, the epitaxial layer 114 can be a second conductive (such as N type) lightly doped layer, including a lightly doped region having second conductive type dopants such as phosphorus, arsenic, nitrogen, etc., in which a concentration of a second conductive dopant in the epitaxial layer 114 is from 10¹⁴ atoms/cm³ to 10¹⁹ atoms/cm³.

Please refer to step S120 of FIG. 1 and FIG. 2B, a first conductive type lightly doped region 120 is formed in the epitaxial layer 114.

In some embodiments, forming the first conductive type lightly doped region 120 includes performing a first conductive type dopant implantation process P1 to make the first conductive type dopants (such as P type dopant, for example, boron, gallium, aluminum, etc.) be implanted into the epitaxial layer 114, and the epitaxial layer 114 is divided into two parts: the lower epitaxial layer 116 and the upper epitaxial layer 118 by the first conductive type lightly doped region 120. In some embodiments, a concentration of the first conductive type dopant in the first conductive type lightly doped region 120 is higher than a concentration of the second conductive type dopant in the epitaxial layer 114 to make the first conductive type lightly doped region 120 mainly have the semiconductor properties of the first conductive type.

Please refer to S130 of FIG. 1, FIG. 2C and FIG. 2D, exemplarily illustrating forming a second conductive type heavily doped region 130 in the upper epitaxial layer 118, and forming the first conductive type heavily doped region 140 in the upper epitaxial layer 118.

In some embodiments, please refer to FIG. 2C, forming the second conductive type heavily doped region 130 includes performing a second conductive dopant implantation process N1 to make the second conductive type dopant (such as phosphorus, arsenic, nitrogen, etc.) be implanted into the upper epitaxial layer 118. In particular, a first photoresist layer PR1 can be disposed first for serving as a barrier layer, and a second conductive dopant implantation process N1 is further performed to form a second conductive type heavily doped region 130 between the neighboring upper epitaxial layers 118, on and neighboring to the first conductive type lightly doped region 120. In some embodiments, a concentration of the second conductive dopant in the second conductive type heavily doped region 130 is higher than a concentration of the dopant in the lower epitaxial layer 116 (such as the second conductive dopant).

In some embodiments, please refer to FIG. 2C and FIG. 2D, forming the first conductive type heavily doped region 140 includes performing a second first conductive type dopant implantation process P2 to make the first conductive type dopants (such as boron, gallium, aluminum, etc.) be implanted into the upper epitaxial layer 118. In particular, a second photoresist layer PR2 can be disposed over the second conductive type heavily doped region 130 first for serving as a barrier layer, and a second first conductive type dopant implantation process P2 is further performed to form a first conductive type heavily doped region 140 in the upper epitaxial layer 118. Therefore, the first conductive type heavily doped region 140 is formed on two sides of the second conductive type heavily doped region 130 and neighboring to the second conductive type heavily doped region 130, making the neighboring first conductive type heavily doped regions 140 (a first conductive type heavily doped region 140A and a first conductive type heavily doped region 140B) are spaced apart by the second conductive type heavily doped region 130. In some embodiments, a concentration of the first conductive type dopant in the first conductive type heavily doped region 140 is higher than a concentration of the first conductive type dopant in the first conductive type lightly doped region 120.

Please refer to step S140 of FIG. 1 and FIG. 2E, a mask M1 is disposed on the second conductive type heavily doped region 130.

In some embodiments, disposing the mask M1 on the second conductive type heavily doped region 130 includes depositing a mask material on the second conductive type heavily doped region 130 and the first conductive type heavily doped region 140, removing the mask material on the first conductive type heavily doped region 140 and on a portion of the second conductive type heavily doped region 130, and making the remained mask material be served as the mask M1. In some embodiments, the material of the mask material includes oxides or nitrides.

Please refer to step S150 of FIG. 1 and FIG. 2F, a spacer SP is disposed on a first sidewall M1a of the mask M1 and a second side wall M1b opposite to the first side wall M1a. That is, a first spacer SP1 is disposed on the first side wall M1a of the mask M1, and a second spacer SP2 is disposed on the second side wall M1b.

In some embodiments, the abovementioned steps include depositing a spacer material (i.e., a material of the spacer SP) extends from the first side wall M1a and the second side wall M1b of the mask M1 to the position on the second conductive type heavily doped region 130 and on the first conductive type heavily doped region 140, and a portion of spacer material on the first conductive type heavily doped region 140 and on the second conductive type heavily doped region 130 is removed by using dry etching. By selecting dry etching, the spacer material is anisotropic etched, and the first spacer SP1 and the second spacer SP2 are respectively remained on the first side wall M1a and the second side wall M1b of the mask M1. A width w1 of the first spacer SP1 and a width w2 of the second spacer SP2 are adjusted by adjusting the procedure parameters (i.e., the width w1 (or the width w2) of which the first spacer SP1 (or the second spacer SP2) is projected on the second conductive type heavily doped region).

Furthermore, it should be emphasized that, through the disposition of the spacer SP, the photomask can be replaced, so that the subsequent anti-breakdown region can be formed through self-alignment to avoid alignment deviations caused by the use of photomasks.

In some embodiments, the spacer material (that is, the material of the spacer SP) includes oxides or nitrides. In some embodiments, the material of the spacer SP and the material of the mask material (mask M1) are different, and the etching selectivity ratio of the mask material to dry etching gas is higher than that of the spacer SP. Therefore, when the spacer material is removed to form the spacer SP, the mask M1 can remain intact. For example, when the material of the mask material is oxides, the material of the spacer SP is nitrides; or when the material of the mask material is nitrides, the material of the spacer SP is oxides.

In some embodiments, in a cross-sectional view, a projection of the spacer SP projected along Z-axis falls within the second conductive type heavily doped region 130 for serving as the mask used for further defining the anti-breakdown region, making sure the anti-breakdown region is at least distributed below the second conductive type heavily doped region 130 and extends form the position below the second conductive type heavily doped region 130 to the position below the first conductive type heavily doped region 140. That is, the anti-breakdown region does not extend from the position below the first conductive type heavily doped region 140 in the direction away from the position below the spacer SP. In some embodiments, the width w1 of which the first spacer SP1 is projected on the second conductive type heavily doped region 130 (e.g., an upper surface of the second conductive type heavily doped region 130) along Z-axis direction (or the width w2 of which the second spacer SP2 is projected on the second conductive type heavily doped region 130) is from 0.1 μm to 1 μm, such as 0.1 μm, 0.2 μm, 0.3 μm, 0.4 μm, 0.5 μm, 0.6 μm, 0.7 μm, 0.8 μm, 0.9 μm, 1 μm or value in any of the aforementioned intervals, which provides a lateral space (for the following formation of the trench) away from the projection of the mask M1 vertically projected on the first conductive type lightly doped region 120, and the space between the anti-breakdown region and the trench subsequently formed can be adjusted. Therefore, if the width w1 (or the width w2) is too wide, the space between the anti-breakdown region and the trench subsequently formed is too wide, improvement on breakdown voltage by the anti-breakdown region is limited; if the width w1 (or the width w2) is too narrow, the space between the anti-breakdown region and the trench subsequently formed is too narrow, excessive electron concentration on the surface of the transistor channel is induced to affect threshold voltage and provides too low carrier mobility, resulting in poor current conduction efficiency.

Please refer to step S160 of FIG. 1 and FIG. 2G, the first conductive type dopant is doped in the first conductive type lightly doped region 120, thereby forming the anti-breakdown region 150 (including a first anti-breakdown region 150A and a second anti-breakdown region 150B located on opposite sides of the first conductive type lightly doped region 120, respectively) in the first conductive type lightly doped region 120. Through the disposition of the anti-breakdown region 150, the threshold voltage of the gate layer subsequently formed can be increased.

In some embodiments, doping the first conductive type dopant in the first conductive type lightly doped region 120 includes performing a third first conductive type dopant implantation process P3, making the first conductive type dopant be implanted into the first conductive type lightly doped region 120 to replace a portion of first conductive type lightly doped region 120 with the anti-breakdown region 150. Therefore, the concentration of the first conductive type dopant in the anti-breakdown region 150 is higher than the concentration of the first conductive type dopant in the first conductive type lightly doped region 120 to fulfill the improvement on breakdown voltage. In some embodiments, the anti-breakdown region 150 can be disposed on or below the first conductive type lightly doped region 120, and neighboring to the first conductive type lightly doped region 120. For example, a bottom surface 151 and a lateral surface 152 (neighboring to the bottom surface 151) of the anti-breakdown region 150 can directly or partially contact the first conductive type lightly doped region 120. As for the top surface 153 of the anti-breakdown region 150, it is coplanar with a top surface 121 of the first conductive type lightly doped region 120. In some embodiments, a concentration of the first conductive type dopant in the anti-breakdown region 150 is slightly higher than a concentration of the first conductive type dopant in the first conductive type lightly doped region 120 to enhance the improvement on threshold voltage of the anti-breakdown region 150.

In some embodiments, the anti-breakdown region 150 (such as the first anti-breakdown region 150A or the second anti-breakdown region 150B) is formed below the second conductive type heavily doped region 130 and the first conductive type heavily doped region 140, neighboring to the second conductive type heavily doped region 130 and the first conductive type heavily doped region 140, and directly contacting the second conductive type heavily doped region 130 and the first conductive type heavily doped region 140. In other words, in a cross-sectional view, a projection of the second conductive type heavily doped region 130 and the first conductive type heavily doped region 140 projected along Z-axis direction covers a projection of the anti-breakdown region 150 projected along Z-axis direction. Through the disposition of the anti-breakdown region 150 extending from the position below the second conductive type heavily doped region 130 to the position below the first conductive type heavily doped region 140, the first conductive type lightly doped region 120 can be replaced on a large scale to further enhance the improvement on threshold voltage by the anti-breakdown region 150. In some other embodiments, the anti-breakdown region 150 can extend from the second conductive type heavily doped region 130 to the lower epitaxial layer 116, making the anti-breakdown region 150 be neighboring to the second conductive type heavily doped region 130 and the lower epitaxial layer 116.

It should be emphasized that, through the design of the first spacer SP1 and the second spacer SP2, the step of forming the anti-breakdown region 150 can be separated from the step of forming the first conductive type lightly doped region 120, making the anti-breakdown region 150 be formed independently, and avoiding the doping concentrations of the first conductive type lightly doped region 120 and the anti-breakdown region 150 interfering with each other. Therefore, the first conductive type lightly doped region 120 and the anti-breakdown region 150 can have different concentrations of the first conductive type dopant, respectively.

Furthermore, the distributions of the first anti-breakdown region 150A and the second anti-breakdown region 150B can also be controlled by adjusting the shape and the width of the first spacer SP1 and the second spacer SP2. For example, when the first spacer SP1 and the second spacer SP2 are disposed mirror-symmetrically with mask M1 as the center of symmetry, the first anti-breakdown region 150A and the second anti-breakdown region 150B are allowed to be disposed mirror-symmetrically with the first conductive type lightly doped region 120, below the mask M1, as the center of symmetry.

Please refer to FIG. 2G and FIG. 2H, after removing the first spacer SP1 and the second spacer SP2, a spacer layer SPL is formed on the second conductive type heavily doped region 130 and the first conductive type heavily doped region 140 again.

In some embodiments, forming the spacer layer SPL includes depositing a spacer material extending from two sides of the mask M1 to the position on the first conductive type heavily doped region 140 and on the second conductive type heavily doped region 130. In some embodiments, the spacer layer SPL is coplanar with the mask M1.

Please refer to step S170 of FIG. 1, FIG. 2H and FIG. 2I, the mask M1 is removed, and the trench 160 is formed and extends into the second conductive type heavily doped region 130, the first conductive type lightly doped region 120 and the epitaxial layer 114.

In some embodiments, the spacer layer SPL is used as a barrier layer, and then the mask M1, the second conductive type heavily doped region 130, the first conductive type lightly doped region 120 and the epitaxial layer 114 are removed by etching to form a trench 160 extending into the second conductive type heavily doped region 130, the first conductive type lightly doped region 120 and the epitaxial layer 114, which provides the subsequent formation of the gate layer. Therefore, the second conductive type heavily doped region 130 is divided into the second conductive type heavily doped region 130A and the second conductive type heavily doped region 130B through the trench 160; the anti-breakdown region 150 is divided into the first anti-breakdown region 150A and the second anti-breakdown region 150B through the trench 160 and the first conductive type lightly doped region 120. In some embodiments, since the etching selectivity ratio of the spacer layer SPL is different from which of the mask M1, the spacer layer SPL maintains intact.

In some embodiments, the second conductive type heavily doped region 130A and the second conductive type heavily doped region 130B neighboring to each other are spaced apart by the trench 160. Furthermore, when the anti-breakdown region 150 extends from the second conductive type heavily doped region 130 to the first conductive type lightly doped region 120, since the trench 160 extends from the position between the spacer layers SPL to the first conductive type lightly doped region 120 and the epitaxial layer 114, a portion of the first conductive type lightly doped region 120 is made to be located between the anti-breakdown region 150 and the trench 160. That is, a first portion 120A of the first conductive type lightly doped region 120 is between the anti-breakdown region 150 and the trench 160, and the second portion 120B of the first conductive type lightly doped region 120 is neighboring to the first portion 120A and located between the epitaxial layer 114 and the first anti-breakdown region 150A. In other embodiments (not shown in figures), when the anti-breakdown region 150 extends from the second conductive type heavily doped region 130 to the lower epitaxial layer 116, the entire first conductive type lightly doped region 120 is between the anti-breakdown region 150 and the trench 160. That is, the first conductive type lightly doped region 120 only has the first portion 120A, but does not have the second portion 120B.

In some embodiments, in the cross-sectional view, a space s1 between the first anti-breakdown region 150A and the trench 160 (or a space s2 between the second anti-breakdown region 150B and the trench 160) is from 0.1 μm to 1 μm, such as 0.1 μm, 0.2 μm, 0.3 μm, 0.4 μm, 0.5 μm, 0.6 μm, 0.7 μm, 0.8 μm, 0.9 μm, 1 μm or value in any of the aforementioned intervals. The space s1 and the space s2 correspond to a width w1 of the first spacer SP1 and a width w2 of the second spacer SP2 in FIG. 2G, respectively. If the space s1 (or the space s2) is too wide, improvement on breakdown voltage improved by the anti-breakdown region 150 after forming the gate layer in the trench 160 is limited; if the space s1 (or the space s2) is too narrow, excessive electron concentration on the surface of the transistor channel is induced to affect threshold voltage and provide too low carrier mobility, resulting in poor current conduction efficiency after forming the gate layer in the trench 160. In some embodiments, when the space s1 (or the space s2) is from 0.4 μm to 0.7 μm, more appropriate balance can be achieved between increasing threshold voltage and maintaining carrier mobility.

Please refer to step S180 of FIG. 1, FIG. 2I and FIG. 2J, the spacer layer SPL is removed. For example, the spacer layer SPL is removed by ashing or etching.

Furthermore, please refer to FIG. 2K, the gate dielectric layer 172 and the gate layer 180 are disposed in the trench 160, an interlayer dielectric layer 174 is formed to cover a gate dielectric layer 172 and a gate layer 180, and a source contact 190 is disposed to cover the interlayer dielectric layer 174, and a semiconductor device 100, Trench Gate Metal-Oxide-Semiconductor Field-Effect Transistor, is formed, in which the gate layer 180 is buried in the dielectric layer 170, and the semiconductor device 100 has bilateral channels towards the first anti-breakdown region 150A and the second anti-breakdown region 150B.

In some embodiments, the gate dielectric layer 172 is located on a bottom surface 161 and a sidewall 162 of the trench 160, and extends to cover the second conductive type heavily doped region 130A and the second conductive type heavily doped region 130B. In some embodiments, the gate layer 180 is disposed on the gate dielectric layer 172 and in the trench 160. In some embodiments, after forming the gate dielectric layer 172 conformally along the bottom surface 161 and the sidewall 162 of the trench 160, the gate layer 180 is formed on the gate dielectric layer 172, and then the interlayer dielectric layer 174 is formed to cover the gate layer 180, the second conductive type heavily doped region 130A and the second conductive type heavily doped region 130B. In some embodiments, the gate dielectric layer 172 and the interlayer dielectric layer 174 include dielectric material, and the gate layer 180 and the source contact 190 include conductive material.

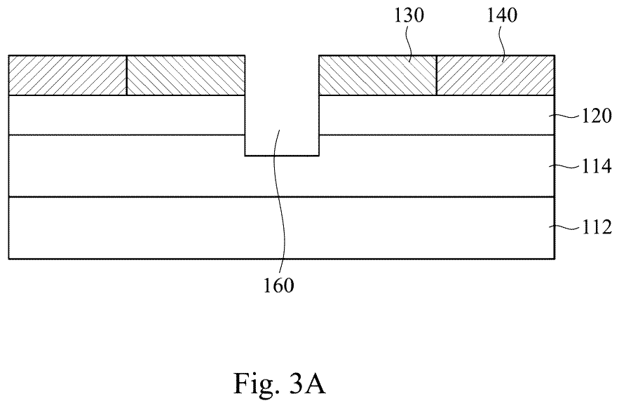

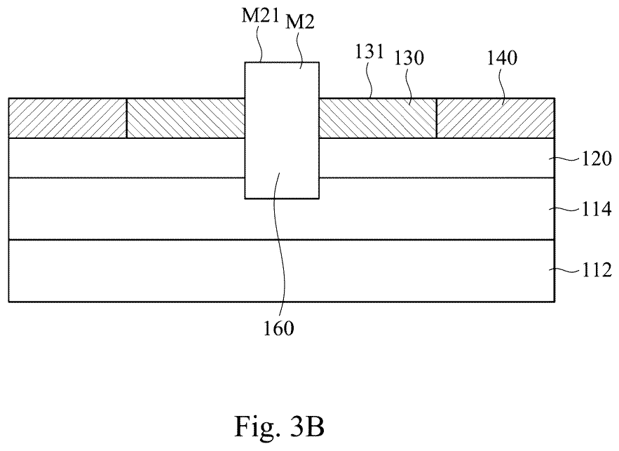

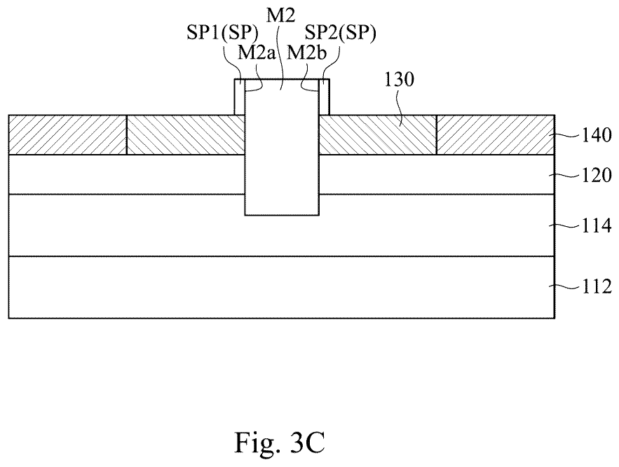

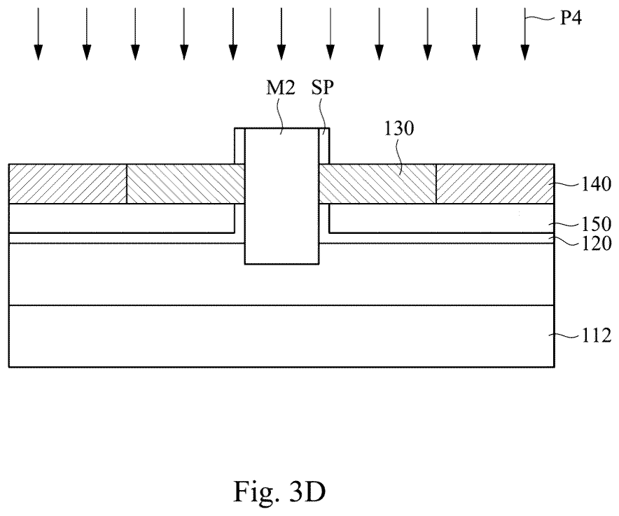

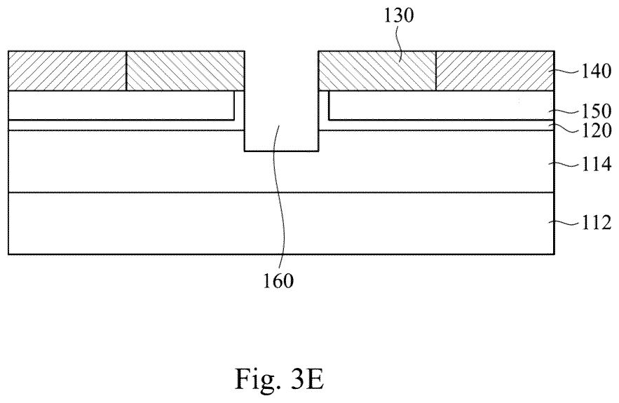

In other embodiments, after forming the trench 160, the anti-breakdown region 150 is then formed, thereby forming a semiconductor device. For example, please refer to FIG. 3A to FIG. 3E, where FIG. 3A is the step after the step S130 of FIG. 1 and FIG. 2D.

First of all, please refer to FIG. 3A, after forming the first conductive type heavily doped region 140 similar to the way of FIG. 2I, the trench 160 is formed, which extends in the second conductive type heavily doped region 130, the first conductive type lightly doped region 120 and the epitaxial layer 114.

In some embodiments, the patterned photoresist can be first formed on the second conductive type heavily doped region 130 and the first conductive type heavily doped region 140, and then the patterned photoresist is removed by ashing or etching after forming the trench 160 by etching.

Please refer to FIG. 3B, the mask M2 is disposed to fill the trench 160.

In some embodiments, a mask material is deposited until filling up the trench 160 and covering the second conductive type heavily doped region 130 and the first conductive type heavily doped region 140, and then the mask material is patterned to form the mask M2. The mask M2 fills up the trench 160 and protrudes from the trench 160. That is, a top surface M21 of the mask M2 is higher than a top surface 131 of the second conductive type heavily doped region 130. In some embodiments, a material of the mask material (the mask M2) can be the same or similar to the mask M1 in FIG. 2E.

Please refer to FIG. 3C, the spacer SP is disposed on a first sidewall M2a and a second sidewall M2b of the mask M2 by the way similar to FIG. 2F.

Please refer to FIG. 3C and FIG. 3D, the first conductive type dopant is doped in the first conductive type lightly doped region 120 by the way similar to FIG. 2G, thereby forming the anti-breakdown region 150, such as performing a fourth first conductive type dopant implantation process P4, making the first conductive type dopant be implanted into the first conductive type lightly doped region 120 to replace a portion of first conductive type lightly doped region 120 with the anti-breakdown region 150.

Please refer to FIG. 3D and FIG. 3E, the mask M2 and the spacer SP are removed to expose the trench 160. For example, the mask M2 is removed by the way similar to FIG. 2I, and the spacer SP is removed by the way similar to the removal of the spacer layer SPL of FIG. 2J.

Furthermore, the semiconductor device 100 can be formed by the way similar to FIG. 2K. It can be understood that, during the manufacturing process, whether to form the anti-breakdown region 150 or the trench 160 first will not affect the structure of semiconductor device 100.

In some other embodiments, the distribution position of the anti-breakdown region 150 can be changed according to practical requirements by adjusting the position of the mask M1 in FIG. 2E, the position of the spacer SP position in FIG. 2F, and the implantation energy of the third first conductive type dopant implantation process P3 in FIG. 2G.

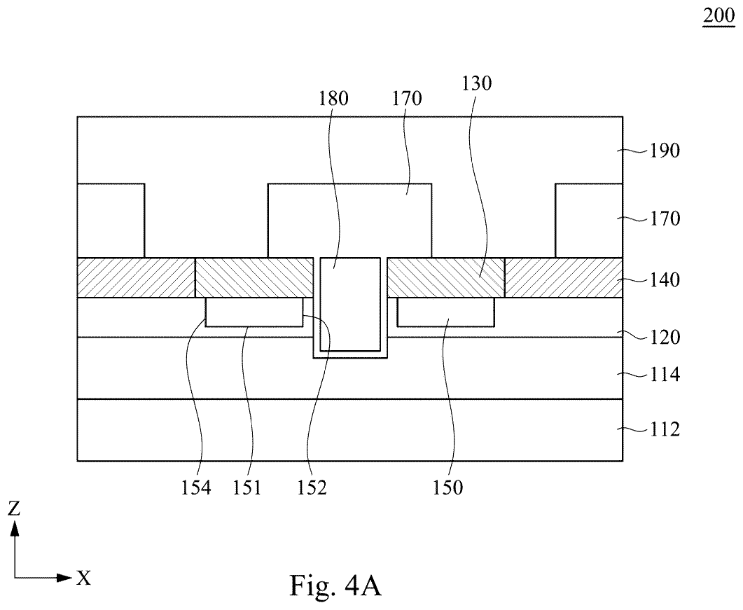

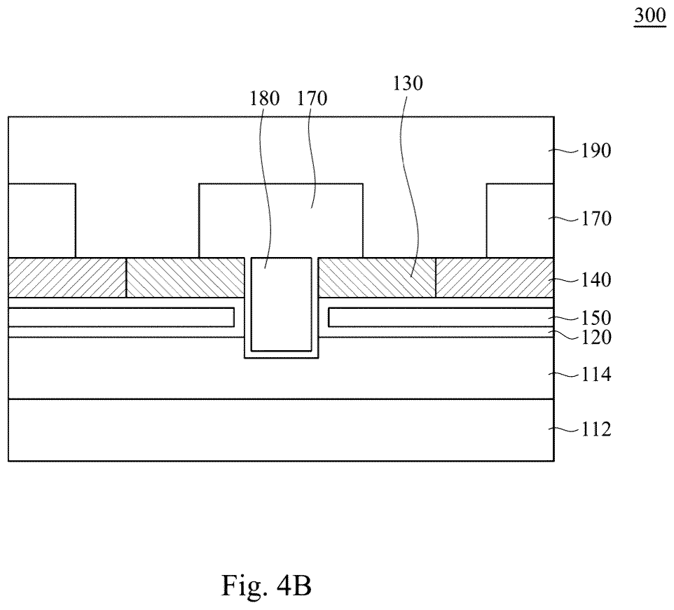

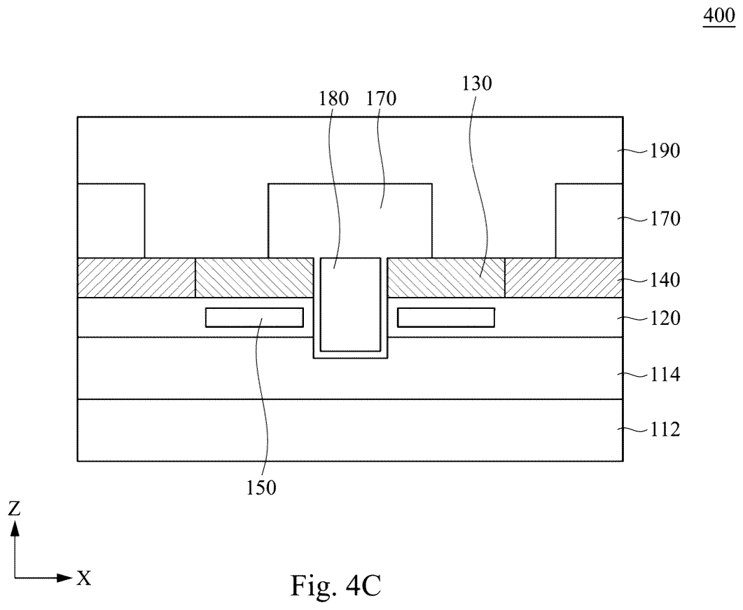

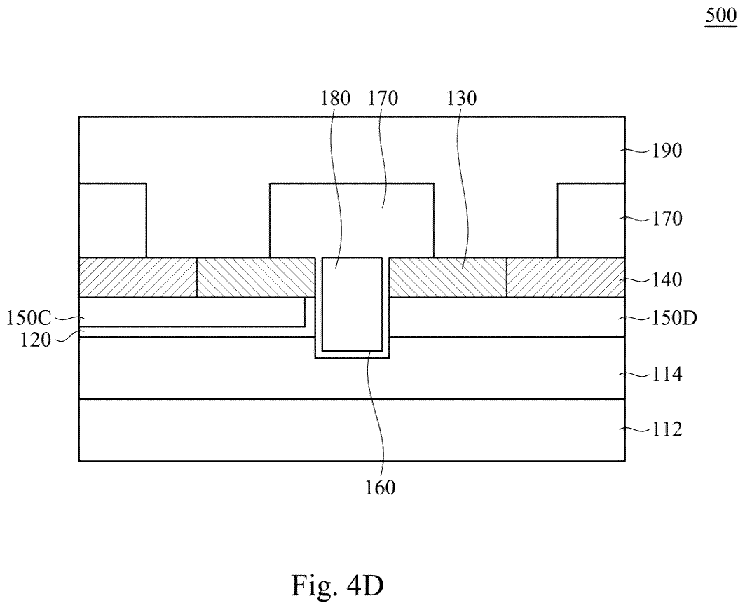

In one other embodiment, please refer to a semiconductor device 200 in FIG. 4A, the positions of the mask M1 and the spacer SP can be adjusted at the step S140 of FIG. 1 (corresponding to FIG. 2E) and the step S150 of FIG. 1 (corresponding to FIG. 2F) to make the position of the anti-breakdown region 150 be disposed below the second conductive type heavily doped region 130 and directly contact the second conductive type heavily doped region 130. Therefore, the bottom surface 151, the lateral surface 152 and the lateral surface 154 of the anti-breakdown region 150 directly contact the first conductive type lightly doped region 120. That is, in the cross-sectional view, the projection of the second conductive type heavily doped region 130 projected along Z-axis direction covers the projection of the anti-breakdown region 150 projected along Z-axis direction, and the projection of the first conductive type heavily doped region 140 projected along Z-axis direction does not cover the projection of the anti-breakdown region 150 projected along Z-axis direction. By reducing the size of the anti-breakdown region 150, the size of the semiconductor device can be saved.

In one other embodiment, please refer to a semiconductor device 300 in FIG. 4B, at the step S160 of FIG. 1 (corresponding to FIG. 2G), the energy used in the third first conductive type dopant implantation process P3 can be adjusted to make the anti-breakdown region 150 be disposed below the second conductive type heavily doped region 130 and the first conductive type heavily doped region 140, and make the first conductive type lightly doped region 120 encapsulate the anti-breakdown region 150. Therefore, in the cross-sectional view, the projection of the second conductive type heavily doped region 130 and the first conductive type heavily doped region 140 projected along Z-axis direction covers the projection of the anti-breakdown region 150 projected along Z-axis direction, the anti-breakdown region 150 and the second conductive type heavily doped region 130 are spaced apart by the first conductive type lightly doped region 120, and the anti-breakdown region 150 and the first conductive type heavily doped region 140 are spaced apart by the first conductive type lightly doped region 120. By encapsulating the anti-breakdown region 150 with the first conductive type lightly doped region 120, the first conductive type dopant of the anti-breakdown region 150 can be prevented from affecting the second conductive type heavily doped region 130 and the first conductive type heavily doped region 140.

In one other embodiment, please refer to a semiconductor device 400 of FIG. 4C, at the step S140 of FIG. 1 (corresponding to FIG. 2E) and the step S150 (FIG. 2F), the positions of the mask M1 and the spacer SP can be adjusted to make the anti-breakdown region 150 be disposed below the second conductive type heavily doped region 130. Therefore, in the cross-sectional view, the projection of the second conductive type heavily doped region 130 projected along Z-axis direction covers the projection of the anti-breakdown region 150 projected along Z-axis direction, and the projection of the first conductive type heavily doped region 140 projected along Z-axis direction does not cover the projection of the anti-breakdown region 150. Furthermore, at the step S160 of FIG. 1 (corresponding to FIG. 2G), the energy used in the third first conductive type dopant implantation process P3 can be adjusted to make the first conductive type lightly doped region 120 encapsulate the anti-breakdown region 150. Therefore, the anti-breakdown region 150 and the second conductive type heavily doped region 130 are spaced apart by the first conductive type lightly doped region 120. By reducing the size of the anti-breakdown region 150, the size of the semiconductor device can be saved. Furthermore, by encapsulating the anti-breakdown region 150 with the first conductive type lightly doped region 120, the first conductive type dopant of the anti-breakdown region 150 can be prevented from affecting the second conductive type heavily doped region 130.

In one other embodiment, please refer to a semiconductor device 500 in FIG. 4D, at the step S150 of FIG. 1 (corresponding to FIG. 2F), the first spacer SP1 is only disposed on the first sidewall M1a of the mask M1, thereby forming the anti-breakdown region 150C and the anti-breakdown region 150D, in which the anti-breakdown region 150C and the trench 160 are spaced apart by the first conductive type lightly doped region 120, and the anti-breakdown region 150D is neighboring to the trench 160 to make the entire first conductive type lightly doped region 120 located on the same side as the anti-breakdown region 150D in the trench 160 be replaced by the anti-breakdown region 150D. Therefore, the semiconductor device of FIG. 4D only has a single side channel towards the anti-breakdown region 150C.

Some embodiments of the present disclosure provide a semiconductor device, in which the anti-breakdown region is formed by doping the first conductive type dopant with higher concentration into the first conductive type lightly doped region to increase threshold voltage. Furthermore, according to a manufacture method of a semiconductor device of the present disclosure, the spacer is disposed on the sidewall of the mask for serving as the barrier layer, and the anti-breakdown region is formed by using self-alignment technique without the definition of the photomask, thereby avoiding alignment deviations derived from the photomask process.

Although this disclosure has been described in detail with respect to certain embodiments, other embodiments are possible. Accordingly, the spirit and scope of the appended claims should not be limited to the embodiments described herein.

What is claimed is:

1. A method of manufacturing a semiconductor device, comprising:
providing a substrate, wherein the substrate comprises a base material and an epitaxial layer on the base material;
forming a first conductive type lightly doped region in the epitaxial layer;
forming a plurality of first conductive type heavily doped regions and a second conductive type heavily doped region in the epitaxial layer on the first conductive type lightly doped region, wherein the plurality of first conductive type heavily doped regions neighboring to each other are spaced apart by the second conductive type heavily doped region;
disposing a mask on the second conductive type heavily doped region;
disposing a spacer on a sidewall of the mask;
doping a first conductive type dopant in the first conductive type lightly doped region, thereby forming an anti-breakdown region;
removing the mask and forming a trench extending into the second conductive type heavily doped region, the first conductive type lightly doped region and the epitaxial layer; and
removing the spacer.

2. The method of claim 1, wherein a material of the mask and a material of the spacer are different.

3. The method of claim 1, wherein in a cross-sectional view, a projection of the spacer projected along a vertical direction falls within the second conductive type heavily doped region.

4. The method of claim 3, wherein in the cross-sectional view, a width of the projection of the spacer projected along the vertical direction and falling within the second conductive type heavily doped region is from 0.1 μm to 1 μm.

5. The method of claim 1, wherein a concentration of the first conductive type dopant in the anti-breakdown region is higher than a concentration of the first conductive type dopant in each of the plurality of first conductive type heavily doped regions.

6. A method of manufacturing a semiconductor device, comprising:
providing a substrate, wherein the substrate comprises a base material and an epitaxial layer on the base material;
forming a first conductive type lightly doped region in the epitaxial layer;
forming a plurality of first conductive type heavily doped regions and a second conductive type heavily doped region in the epitaxial layer on the first conductive type lightly doped region, wherein the plurality of first conductive type heavily doped regions neighboring to each other are spaced apart by the second conductive type heavily doped region;
forming a trench extending into the second conductive type heavily doped region, the first conductive type lightly doped region and the epitaxial layer;
disposing a mask filling the trench, wherein a top surface of the mask is higher than a top surface of the second conductive type heavily doped region;
disposing a spacer on a sidewall of the mask;
doping a first conductive type dopant in the first conductive type lightly doped region, thereby forming an anti-breakdown region; and
removing the mask and the spacer to expose the trench.

7. The method of claim 6, wherein the step of disposing the mask filling the trench comprises making the mask fill up the trench and protrude from the trench.

8. A semiconductor device, comprising:
a substrate, comprising a base material and an epitaxial layer on the base material;
a first conductive type lightly doped region disposed on the epitaxial layer;
an anti-breakdown region disposed in the first conductive type lightly doped region, wherein a bottom surface of the anti-breakdown region and a lateral surface of the anti-breakdown region neighboring to the bottom surface directly contact the first conductive type lightly doped region, wherein a concentration of a first conductive type dopant in the anti-breakdown region is higher than a concentration of the first conductive type dopant in the first conductive type lightly doped region;
a plurality of second conductive type heavily doped regions neighboring to the first conductive type lightly doped region and the anti-breakdown region, wherein the plurality of second conductive type heavily doped regions neighboring to each other are spaced apart by a trench, and the trench extends from a position between the plurality of second conductive type heavily doped regions to the first conductive type lightly doped region and the epitaxial layer, making the first conductive type lightly doped region be located between the anti-breakdown region and the trench; and
a plurality of first conductive type heavily doped regions, wherein each of the plurality of first conductive type heavily doped regions is neighboring to each of the plurality of second conductive type heavily doped regions.

9. The semiconductor device of claim 8, wherein in a cross-sectional view, a space between the anti-breakdown region and the trench is from 0.1 μm to 1 μm.

10. The semiconductor device of claim 8, further comprising:
a gate dielectric layer disposed on the trench, and
a gate layer disposed on the gate dielectric layer.

11. The semiconductor device of claim 8, wherein the anti-breakdown region directly contacts each of the plurality of second conductive type heavily doped regions.

12. The semiconductor device of claim 8, wherein the first conductive type lightly doped region encapsulates the anti-breakdown region to make the anti-breakdown region and each of the plurality of second conductive type heavily doped regions be spaced apart by the first conductive type lightly doped region.

13. The semiconductor device of claim 8, wherein in a cross-sectional view, a projection of each of the plurality of second conductive type heavily doped regions and each of the plurality of first conductive type heavily doped regions projected along a vertical direction covers a projection of the anti-breakdown region projected along the vertical direction.

14. The semiconductor device of claim 8, wherein in a cross-sectional view, a projection of each of the plurality of second conductive type heavily doped regions projected along a vertical direction covers a projection of the anti-breakdown region projected along the vertical direction.

15. The semiconductor device of claim 8, wherein the anti-breakdown region comprises a first anti-breakdown region and a second anti-breakdown region, and the first anti-breakdown region and the second anti-breakdown region are located on opposite sides of the trench, respectively.
